(19) United States
(12) Patent Application Publication
(10) Pub. No.: US 2011/0133599 A1
(43) Pub. Date: Jun. 9, 2011

(54) SURFACE ACOUSTIC WAVE SENSOR

(75) Inventors: Shigeo ITO, Ritto-shi (JP); Michio KADOTA, Kyoto-shi (JP); Yoshihiro ITO, Yasu-shi (JP); Yuri HOSHINO, Yasu-shi (JP)

(73) Assignee: MURATA MANUFACTURING CO., LTD., Nagaokakyo-shi (JP)

(21) Appl. No.: 13/020,064

(22) Filed: Feb. 3, 2011

Related U.S. Application Data
(63) Continuation of application No. PCT/JP2009/003810, filed on Aug. 7, 2009.

(30) Foreign Application Priority Data
Aug. 18, 2008 (JP) 2008-209879

(51) Int. Cl. H01L 41/00

(52) U.S. Cl. 310/313 A

(57) ABSTRACT

A surface acoustic wave sensor is capable of detecting a specific detection object with high accuracy and is excellent in economy. The surface acoustic wave sensor includes a piezoelectric substrate and a comb shaped electrode disposed on the piezoelectric substrate to detect a specific detection object on the basis of a change in output signal. At least a portion of the comb shaped electrode is electrically conductive and is made of a sensitive material which responds to the above-described specific detection object.

### BACKGROUND OF THE INVENTION

1. Field of the Invention

The present invention relates to a surface acoustic wave sensor. In particular, the present invention relates to a surface acoustic wave sensor including a piezoelectric substrate and a comb shaped electrode disposed on the piezoelectric substrate to detect a specific detection object on the basis of a change in output signal.

2. Description of the Related Art

Various sensors using a surface acoustic wave have been proposed previously. For example, Japanese Unexamined Patent Application Publication No. 2005-331326 described below discloses a surface acoustic wave sensor 200 provided with a structure shown in FIG. 11 and FIG. 12.

As shown in FIG. 11 and FIG. 12, the surface acoustic wave sensor 200 includes comb shaped electrodes 220 and reflectors 230 disposed on a piezoelectric substrate 210 and a reaction film 240, which is disposed on the comb shaped electrodes 220 and the reflectors 230, which reacts with a specific substance, and which is a self-organizing monomolecular film. In this surface acoustic wave sensor 200, a specific substance is detected on the basis of a change in frequency of an output signal resulting from reaction of the reaction film 240 with the specific substance.

In the surface acoustic wave sensor 200 shown in FIG. 11 and FIG. 12, when a detection object substance comes into contact with the reaction film 240 disposed on the comb shaped electrodes 220 and the reflectors 230, the detection object substance is adsorbed by the reaction film 240 in accordance with the state of the specific substance. When the detection object substance is adsorbed, the mass of the reaction film 240 increases. Along with this change, the mass added to the comb shaped electrodes 220 and the reflectors 230 located under the reaction film 240 increases, and the propagation velocity of an elastic wave propagated is reduced. It becomes possible to output as a change in frequency of an output signal on the basis of a change in propagation velocity of the elastic wave. It is possible to detect presence or absence of the specific substance, which is the detection object, the concentration, or the like.

However, regarding the surface acoustic wave sensor 200, since the reaction film 240 is disposed on the comb shaped electrodes 220, the production steps are complicated, there are no economies of scale or low costs in manufacturing, and large variations result. Furthermore, there is a problem in that an influence of the reaction film is transferred to the piezoelectric substrate surface through the comb shaped electrodes and, thereby, the sensor sensibility is not obtained sufficiently.

### SUMMARY OF THE INVENTION

Accordingly, preferred embodiments of the present invention solve such problems and provide a surface acoustic wave sensor to detect a specific detection object with high accuracy and that is excellent in economy.

In a preferred embodiment of the present invention, a surface acoustic wave sensor includes a piezoelectric substrate and a comb shaped electrode disposed on the piezoelectric substrate and detects a specific detection object on the basis of a change in output signal, wherein at least a portion of the comb shaped electrode is electrically conductive and is made of a sensitive material which responds to the specific detection object. According to this configuration, a change in a property of a sensitive film is transferred directly to the piezoelectric substrate surface, so that improvement in sensor sensitivity is achieved.

In a specific preferred embodiment of the present invention, a reflector disposed on the piezoelectric substrate may preferably be also included.

In another preferred embodiment of the present invention, a surface acoustic wave sensor includes a piezoelectric substrate, a comb shaped electrode disposed on the piezoelectric substrate, and a reflector disposed on the piezoelectric substrate so as to detect a specific detection object on the basis of a change in output signal, wherein at least a portion of the reflector includes a sensitive material which responds to the specific detection object. According to this configuration, the electrical conductivity of the sensitive material is not indispensable. Therefore, the range of choices of the sensitive material is increased, a more appropriate material can be chosen, and a sensor with higher accuracy can be obtained.

In another specific preferred embodiment of the present invention, the sensitive material constituting the reflector is electrically conductive. According to this configuration, a large reflection coefficient can be used, the number of lines of the reflector can be reduced, and the element size can be reduced.

In another specific preferred embodiment of the present invention, the comb shaped electrode or the reflector is in contact with the piezoelectric substrate.

In another specific preferred embodiment of the present invention, the whole of at least one of the comb shaped electrode and the reflector is made of the sensitive material. According to this configuration, the sensor sensitivity can be further improved.

In another specific preferred embodiment of the present invention, the whole of the comb shaped electrode and the whole of the reflector are made of the sensitive material. According to this configuration, the sensor sensitivity can be further improved and, in addition, effects are exerted on simplification of the production process and cost reduction.

In another specific preferred embodiment of the present invention, the whole of the reflector is made of the sensitive material. According to this configuration, the sensor sensitivity can be further improved.

In another specific preferred embodiment of the present invention, the comb shaped electrode and the reflector include portions made of mutually different types of the sensitive materials. In this case, for example, the detectable temperature range of the surface acoustic wave sensor can be extended by using a plurality of types of sensitive materials having different detectable temperature ranges. Furthermore, for example, a plurality of types of detection objects can be detected with one surface acoustic wave sensor by using a plurality of types of sensitive materials having different detection objects. Consequently, expansion in functionality and miniaturization of the surface acoustic wave sensor can be facilitated.

In another specific preferred embodiment of the present invention, the surface acoustic wave sensor is provided with a plurality of comb shaped electrodes, wherein the plurality of comb shaped electrodes include a plurality of types of comb shaped electrodes made of mutually different types of the above-described sensitive materials.

In another specific preferred embodiment of the present invention, the surface acoustic wave sensor is provided with a plurality of the reflectors, wherein the plurality of reflectors include a plurality of types of reflectors made of mutually different types of the above-described sensitive materials.

In another specific preferred embodiment of the present invention, the mutually different types of the sensitive materials respond to detection objects different from each other.

In a preferred embodiment of the present invention, the detection object is not specifically limited. Preferable examples of detection objects include fluids containing at least one type of hydrogen, nitrogen oxides, carbon monoxide, and the like. Most of all, a fluid containing hydrogen is further preferable. In the case where the detection object is the fluid containing hydrogen, specific examples of sensitive materials include a hydrogen absorbing metal and a hydrogen absorbing alloy. Specific examples of hydrogen absorbing metals include Ti and Pd. Furthermore, specific examples of hydrogen absorbing alloys include Ni—Pd, TiFe, and Mg—Ni. The surface acoustic wave sensor according to various preferred embodiments of the present invention can detect specific detection object with high accuracy by choosing a sensitive material suitable for the detection object and, thereby, a surface acoustic wave sensor excellent in economy can be provided.

In this regard, the sensitive material refers to a material which responds to a specific substance. For example, the sensitive material may be a material which responds to a specific substance and, thereby, a property thereof is changed or a material which acts on a specific substance on the basis of a catalytic effect. More specifically, the sensitive material may be, for example, a material, which absorbs, or releases a specific substance and, thereby, a property is changed, and a material, which interacts with a specific substance and, thereby, a property is changed.

In this regard, the change in property of the sensitive material is, for example, a change in resistance value or a change in mass, and is not specifically limited insofar as the change has an influence on the elastic wave characteristic, e.g., a propagation loss or a propagation velocity, of a surface acoustic wave generated in a comb shaped electrode.

In various preferred embodiments of the present invention, at least a portion of the comb shaped electrode is electrically conductive and is made of the sensitive material which responds to the specific detection object or at least a portion of the reflector is made of the sensitive material which responds to the specific detection object. Therefore, the production steps can be simplified as compared with those of a surface acoustic wave sensor, in which a reaction film is disposed on the comb shaped electrode and the reflector. Consequently, variations in accuracy, which are accumulated in a plurality of production steps, become small. Furthermore, since the sensitive material acts directly on the piezoelectric substrate, a high-sensitivity surface acoustic wave sensor excellent in economy can be provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view of a surface acoustic wave sensor according to a first preferred embodiment of the present invention.

FIG. 2 is a schematic sectional view of the section taken along a line A-A shown in FIG. 1.

FIG. 3 is a schematic plan view of a surface acoustic wave sensor according to a second preferred embodiment of the present invention.

FIG. 4 is a schematic plan view of a surface acoustic wave sensor according to a third preferred embodiment of the present invention.

FIG. 5 is a schematic plan view of a surface acoustic wave sensor according to a fourth preferred embodiment of the present invention.

FIG. 6 is a schematic plan view of a surface acoustic wave sensor according to a fifth preferred embodiment of the present invention.

FIG. 7 is a schematic plan view of a surface acoustic wave sensor according to a sixth preferred embodiment of the present invention.

FIG. 8 is a schematic plan view of a surface acoustic wave sensor according to a seventh preferred embodiment of the present invention.

FIG. 9 is a schematic plan view of a surface acoustic wave sensor according to an eighth preferred embodiment of the present invention.

FIG. 10 is a schematic plan view of a surface acoustic wave sensor according to a ninth preferred embodiment of the present invention.

FIG. 11 is a schematic plan view of a surface acoustic wave sensor described in Japanese Unexamined Patent Application Publication No. 2005-331326.

FIG. 12 is a schematic sectional view of the section taken along a line B-B shown in FIG. 11.

### DETAILED DESCRIPTION OF THE PREFERRED EMBODIMENTS

The present invention will be made clear by explaining specific preferred embodiments according to the present invention with reference to the drawings.

### First Preferred Embodiment

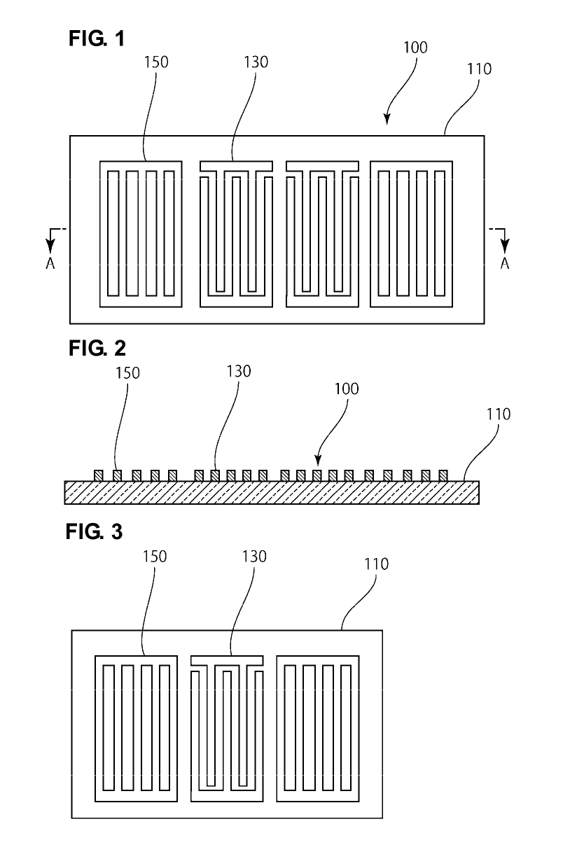

FIG. 1 is a schematic plan view of a 2-port resonator type surface acoustic wave sensor according to a first preferred embodiment of the present invention. FIG. 2 is a schematic sectional view showing the electrode structure along a line A-A shown in FIG. 1.

A surface acoustic wave sensor 100 shown in FIG. 1 and FIG. 2 is an apparatus which detects a specific detection object on the basis of a change in output signal. As shown in FIG. 1 and FIG. 2, the surface acoustic wave sensor 100 is preferably provided with a piezoelectric substrate 110 and four comb shaped electrodes 130 and one pair of grating reflectors 150 disposed on the piezoelectric substrate 110, for example. The four comb shaped electrodes constitute two comb shaped electrode pairs. Each comb shaped electrode pair constitutes an IDT electrode. The one pair of reflectors 150 are arranged to sandwich the two comb shaped electrode pairs. That is, the one pair of reflectors 150 are disposed on both sides of a region, in which two IDT electrodes composed of four comb shaped electrodes 130 are disposed, in the elastic wave propagation direction.

In the present preferred embodiment, the comb shaped electrodes 130 and the reflectors 150 are made of a sensitive material that is electrically conductive and responds to a specific detection object.

In this regard, specifically, the whole of the comb shaped electrodes 130 and the whole of the reflectors 150 are preferably made of the above-described sensitive material in the present preferred embodiment. However, the present invention is not limited to this configuration. For example, one of a portion of the comb shaped electrodes 130 and a portion of the reflectors 150 may be made of a material other than the sensitive material. In that case, it is preferable that the portion of the comb shaped electrodes 130 and the portion of the reflectors 150 may be made of an electrically conductive sensitive material. Alternatively, for example, the whole of at least one of the comb shaped electrodes 130 and the reflectors 150 may be made of a material other than the sensitive material. Alternatively, the reflectors 150 may be made of a sensitive material not having the electrical conductivity.

In the present preferred embodiment, the piezoelectric substrate 110 is preferably formed from quartz. Specifically, the piezoelectric substrate 110 is composed of a 36 degree to 60 degree Y-cut X-direction propagation quartz substrate. However, in the present invention, the piezoelectric substrate 110 is not specifically limited. The piezoelectric substrate 110 may be made of other piezoelectric single crystals, e.g., LiTaO₃ or LiNbO₃. Alternatively, the piezoelectric substrate 110 may be made of piezoelectric ceramic, e.g., PZT based ceramic.

A method for manufacturing the surface acoustic wave sensor 100 is not specifically limited. For example, the surface acoustic wave sensor 100 can be produced by forming the comb shaped electrodes 130 and the reflectors 150 on the piezoelectric substrate 110 from a sensitive material following the publicly known forming method. Specific examples of methods for forming the comb shaped electrodes 130 and the reflectors 150 include thin film forming methods, e.g., a sputtering method, an evaporation method, and a plating method, for example.

The thicknesses of the comb shaped electrode 130 and the reflector 150 are not specifically limited. The thicknesses of the comb shaped electrode 130 and the reflector 150 can be specified to be, for example, about 5 nm to 200 nm.

Furthermore, in order to improve the adhesion of the comb shaped electrodes 130 and the reflectors 150 to the piezoelectric substrate 110, an adhesive layer made of Cr, Ti, or the like may be disposed between the comb shaped electrodes 130 or the reflectors 150 and the piezoelectric substrate 110. The adhesive layer can be formed by the thin film forming method, e.g., a sputtering method, an evaporation method, or a plating method, for example. The thickness of the adhesive layer can be specified to be, for example, about 5 nm to 10 nm.

In the surface acoustic wave sensor 100, the comb shaped electrodes 130 and the reflectors 150 are made of Pd, which is one type of hydrogen absorbing metal. Consequently, when a detection object containing hydrogen comes into contact with the comb shaped electrodes 130 and the reflectors 150, hydrogen is absorbed by the comb shaped electrodes 130 and the reflectors 150.

Next, a method for detecting hydrogen by using the surface acoustic wave sensor 100 will be described. Initially, a standard specimen A containing a predetermined concentration of hydrogen and a standard specimen B not containing hydrogen are prepared. Subsequently, the surface acoustic wave sensor 100 is brought into contact with each of the standard specimen A and the standard specimen B, and in each case, the frequency of the output signal of the surface acoustic wave sensor 100 is measured.

Then, a specimen C containing an unknown concentration of hydrogen is brought into contact with the surface acoustic wave sensor 100, and the frequency of the output signal of the surface acoustic wave sensor 100 in that case is measured.

Thereafter, the measurement results of the standard specimen A containing hydrogen and the standard specimen B not containing hydrogen and the measurement result of the unknown specimen C are compared and, thereby, presence or absence and the concentration of hydrogen contained in the specimen C can be detected.

In this regard, in the case where a calibration curve is formed in advance, the hydrogen concentration in the specimen can be detected by merely conducting the measurement of the unknown specimen. That is, the hydrogen concentration in the specimen can be detected by comparing the measurement result of the unknown specimen and the calibration curve.

In this regard, the calibration curve can be prepared in the following procedure. Initially, a plurality of standard specimens containing known concentrations of hydrogen are prepared in advance. Each of the plurality of standard specimens is brought into contact with the surface acoustic wave sensor 100 and the frequency of the output signal in each case is measured. Thereafter, the calibration curve can be formed on the basis of the measurement results.

In order to measure the frequency of the output signal when the specimen comes into contact with the surface acoustic wave sensor 100, initially, an oscillating circuit is connected to the surface acoustic wave sensor 100. Subsequently, a surface acoustic wave is excited by the comb shaped electrodes 130, and the frequency of the output signal of the surface acoustic wave sensor 100 at that time may be measured by using a frequency meter or the like.

Incidentally, in the first preferred embodiment, the case where Pd serving as a hydrogen absorbing metal is used as the sensitive material is described. However, in the present invention, the sensitive material is not limited to Pd. The sensitive material may be, for example, an organic material or an inorganic material, which absorbs hydrogen, other than Pd. Examples of inorganic materials, which absorb hydrogen, other than Pd include hydrogen absorbing metals, e.g., Ni, and hydrogen absorbing alloys, e.g., TiFe and Mg—Ni.

Furthermore, the sensitive material can be chosen appropriately in accordance with the type of the specific detection object. For example, in the case where carbon monoxide is detected, the sensitive material can be specified to be a material, e.g., ZnO, SnO, or Pt. Moreover, in the case where the nitrogen oxide is detected, the sensitive material can be specified to be a material, e.g., ZrO₂.

In addition, in the present preferred embodiment, an example, in which the comb shaped electrodes 130 and the reflectors 150 made of the sensitive material are in contact with the piezoelectric substrate 110, is explained. However, the present invention is not limited to this configuration. For example, the comb shaped electrode 130 may have a monolithic structure of a general electrode, e.g., Al, and a sensitive material having the electrical conductivity. In this case, the sensitive material is not directly in contact with the piezoelectric substrate 110.

Other examples of preferred embodiments of the present invention will be described below. In this regard, in the following explanation, the elements having the functions substantially common to those in the above-described first preferred embodiment are represented by the same reference numerals, and explanations thereof will not be provided.

### Second Preferred Embodiment

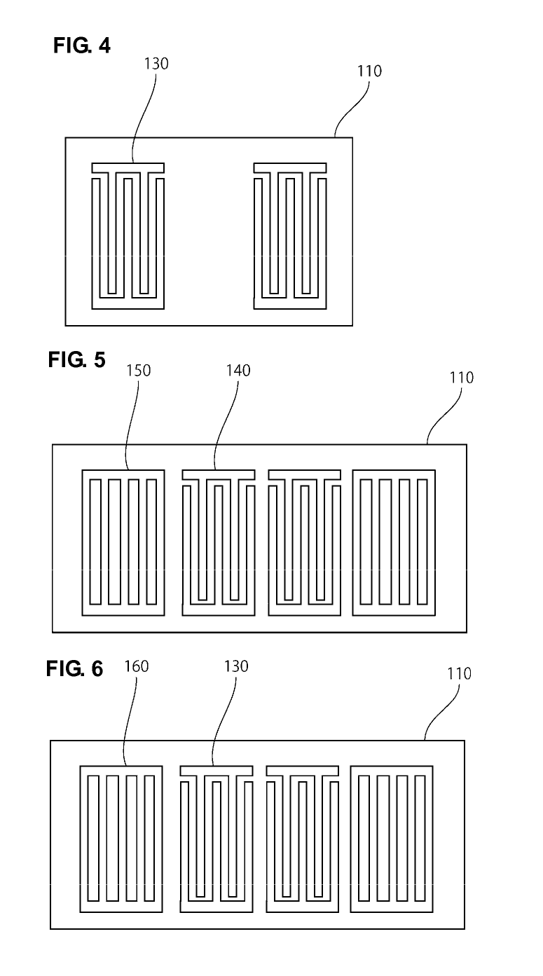

FIG. 3 is a schematic plan view of a surface acoustic wave sensor according to the second preferred embodiment. In the above-described first preferred embodiment, the 2-port resonator type surface acoustic wave sensor is explained as an example. However, in the present invention, the surface acoustic wave sensor is not limited to the 2-port resonator type surface acoustic wave sensor. For example, as shown in FIG. 3, the surface acoustic wave sensor may be a sensitive material 1-port resonator type surface acoustic wave sensor.

### Third Preferred Embodiment

FIG. 4 is a schematic plan view of a surface acoustic wave sensor according to the third preferred embodiment. In the above-described first and second preferred embodiments, the surface acoustic wave sensors including the reflectors are explained as examples. However, the present invention is not limited to the surface acoustic wave sensor including the reflector. For example, as shown in FIG. 4, the surface acoustic wave sensor may be a so-called transversal type surface acoustic wave sensor, in which a propagation path is provided between two IDT electrodes composed of interdigitated two comb shaped electrodes 130.

### Fourth and Fifth Preferred Embodiments

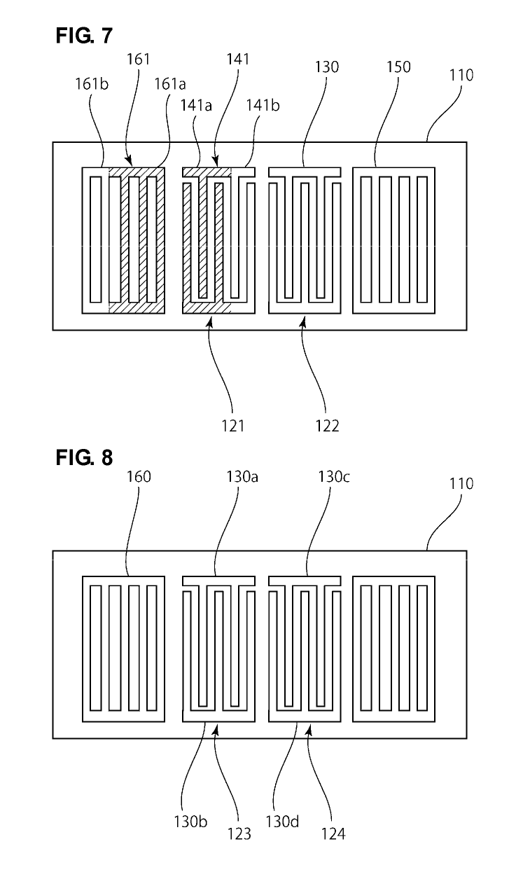

FIG. 5 is a schematic plan view of a surface acoustic wave sensor according to a fourth preferred embodiment of the present invention. Furthermore, FIG. 6 is a schematic plan view of a surface acoustic wave sensor according to a fifth preferred embodiment of the present invention.

In the above-described first to third preferred embodiments, the examples, in which both the comb shaped electrode and the reflector constituting the IDT electrode are preferably made of the electrically conductive sensitive material, are explained. However, the present invention is not limited to this configuration. For example, as shown in FIG. 5, comb shaped electrodes 140 made of an electrically conductive material, which is not a sensitive material, may be disposed in place of the comb shaped electrodes 130 made of the sensitive material. In this case, the resistance value of the IDT electrode is reduced relatively easily.

In this regard, specific examples of electrically conductive materials for forming the comb shaped electrodes 140 include Al and Au.

Furthermore, as shown in FIG. 6, reflectors 160 made of sensitive material not having the electrical conductivity may be disposed in place of the reflectors 150 made of the electrically conductive sensitive material. In this case, the range of choices of the material for the reflector 160 is extended. For example, a material, for example, a metal oxide, e.g., ZrO₂, which is more suitable for detection, can be chosen in accordance with a specific detection object. Consequently, the specific detection object can be detected with higher accuracy.

### Sixth Preferred Embodiment

FIG. 7 is a schematic plan view of a surface acoustic wave sensor according to the sixth preferred embodiment.

In the above-described first preferred embodiment, the example, in which the whole of the two IDT electrodes and the whole of the pair of reflectors are made of the electrically conductive sensitive material, is explained. However, the present invention is not limited to this configuration. For example, as shown in FIG. 7, a portion not made of a sensitive material may be disposed in at least one of the two IDT electrodes and the pair of reflectors. That is, at least one of the two IDT electrodes and the pair of reflectors may have a portion made of a sensitive material and a portion not made of a sensitive material. For example, at least one of the two IDT electrodes and the pair of reflectors may have electrode fingers made of a sensitive material and electrode fingers not made of a sensitive material.

Specifically, as shown in FIG. 7, in the present preferred embodiment, one IDT electrode 122 of two IDT electrodes 121 and 122 preferably includes one pair of comb shaped electrodes 130 made of an electrically conductive sensitive material, and the other IDT electrode 121 preferably includes one pair of comb shaped electrodes 141, a portion of which is made of an electrically conductive sensitive material and a remainder portion of which is made of a material other than the sensitive material. That is, the comb shaped electrodes 141 includes a portion 141a made of the electrically conductive sensitive material and a portion 141b made of the material other than the sensitive material. In this regard, in FIG. 7, the portion 141a and a portion 161a described later are hatched for convenience of explanation.

Moreover, in the present preferred embodiment, one of the pair of reflectors is composed of the reflector 150 made of an electrically conductive sensitive material, and the other reflector is composed of a reflector 161, a portion of which is made of the electrically conductive sensitive material and a remainder portion of which is made of a material other than the sensitive material. That is, the reflector 161 includes a portion 161a made of the electrically conductive sensitive material and a portion 161b made of the material other than the sensitive material.

In the present preferred embodiment, the sensitivity of the surface acoustic wave sensor can be adjusted by changing the ratio of the portion 141a made of the electrically conductive sensitive material of the comb shaped electrodes 141 to the portion 141b made of the material other than the sensitive material of the comb shaped electrodes 141 or the ratio of the portion 161a made of the electrically conductive sensitive material of the reflector 161 to the portion 161b made of the material other than the sensitive material of the reflector 161.

### Seventh to Ninth Preferred Embodiments

In the above-described first preferred embodiment, the case where the two IDT electrodes and the pair of reflectors are formed from the same type of electrically conductive sensitive material, is explained. However, the present invention is not limited to this configuration. For example, portions made of mutually different types of sensitive materials may be present in the comb shaped electrodes and the reflectors. Specifically, a plurality of comb shaped electrodes may be disposed and the plurality of comb shaped electrodes may include a plurality of types of comb shaped electrodes made of mutually different types of sensitive materials. Furthermore, a plurality of reflectors may be disposed and the plurality of reflectors may include a plurality of types of reflectors made of mutually different types of sensitive materials. In these cases, the mutually different types of sensitive materials may respond to the same detection object or respond to detection objects different from each other. In the case where the mutually different types of sensitive materials respond to the same detection object, for example, it is preferable that the mutually different types of sensitive materials have different detection characteristics, e.g., detectable temperature ranges.

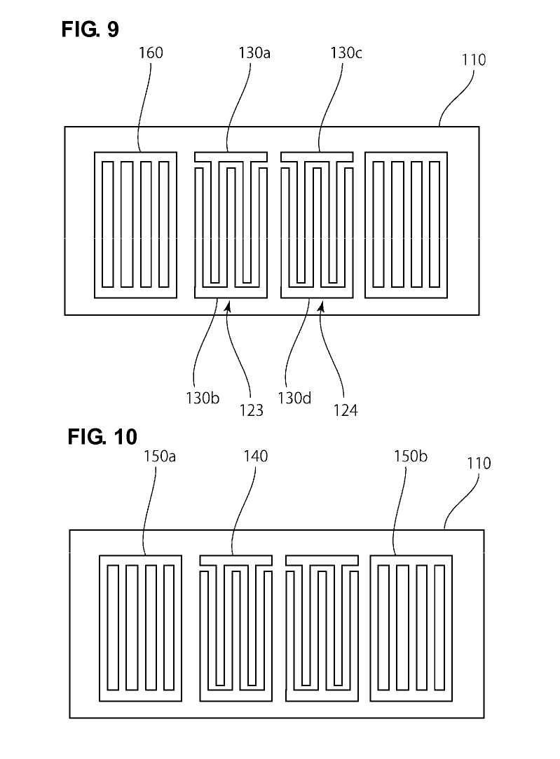

FIG. 8 is a schematic plan view of a surface acoustic wave sensor according to a seventh preferred embodiment of the present invention.

As shown in FIG. 8, in the seventh preferred embodiment, IDT electrodes 123 and 124 are disposed along the surface acoustic wave propagation direction. The IDT electrode 123 includes one interdigitated pair of comb shaped electrodes 130a and 130b. Furthermore, the IDT electrode 124 includes one interdigitated pair of comb shaped electrodes 130c and 130d. In the present preferred embodiment, the comb shaped electrodes 130a and 130b and the comb shaped electrodes 130c and 130d are made of mutually different types of electrically conductive sensitive materials.

For example, the comb shaped electrodes 130a and 130b and the comb shaped electrodes 130c and 130d are made of sensitive materials which respond to the same substance but which have different detectable temperature ranges. Consequently, the detectable temperature range of the specific detection object can be increased as compared with that in the case where the comb shaped electrodes 130a and 130b and the comb shaped electrodes 130c and 130d are made of the same type of sensitive material.

In this regard, in the case where the detection object is hydrogen, examples of sensitive materials having different detectable temperature ranges include Pd and MgNi.

Alternatively, for example, the comb shaped electrodes 130a and 130b and the comb shaped electrodes 130c and 130d are made of electrically conductive sensitive materials which respond to different substances. Specifically, for example, the comb shaped electrodes 130a and 130b are made of a sensitive material, e.g., Pd, which responds to hydrogen, and the comb shaped electrodes 130c and 130d are made of a sensitive material, e.g., Pt, which responds to carbon monoxide. Consequently, a plurality of types of detection objects can be detected, and there are effects that expansion in functionality, miniaturization, and reduction in power consumption of the surface acoustic wave sensor can be facilitated.

FIG. 9 is a schematic plan view of a surface acoustic wave sensor according to an eighth preferred embodiment of the present invention.

As shown in FIG. 9, in the eighth preferred embodiment, one comb shaped electrode 130a of the IDT electrode 123 and one comb shaped electrode 130c of the IDT electrode 124 are made of an electrically conductive sensitive material, the type of which is different from the type of an electrically conductive sensitive material for the other comb shaped electrodes 130b and 130d. In this case as well, in a manner similar to that in the above-described seventh preferred embodiment, improvement in performance, expansion in functionality, miniaturization, and reduction in power consumption of the surface acoustic wave sensor can be facilitated.

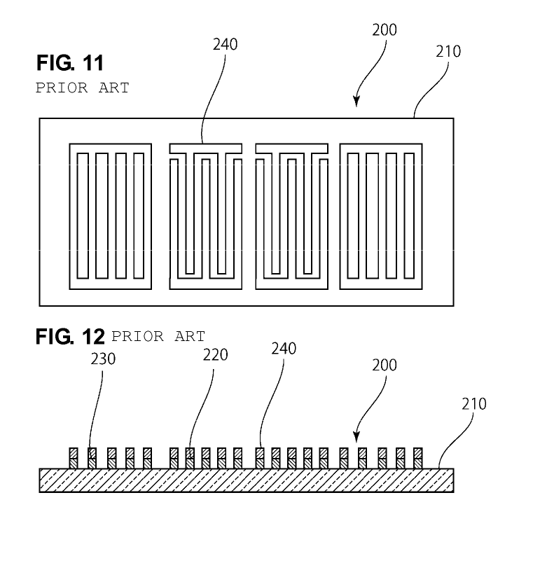

FIG. 10 is a schematic plan view of a surface acoustic wave sensor according to a ninth preferred embodiment of the present invention. As shown in FIG. 10, in the ninth preferred embodiment, a pair of grating reflectors 150a and 150b disposed on both sides in the elastic wave propagation direction of two IDT electrodes composed of two pairs of comb shaped electrodes are made of mutually different types of sensitive materials. In this case as well, in a manner similar to that in the above-described seventh preferred embodiment, improvement in performance, expansion in functionality, miniaturization, and reduction in power consumption of the surface acoustic wave sensor can be facilitated.

Furthermore, in the present preferred embodiment, the grating reflectors 150a and 150b may be made of a sensitive material having the electrical conductivity or be made of a sensitive material not having the electrical conductivity.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A surface acoustic wave sensor comprising:
a piezoelectric substrate; and
a comb shaped electrode disposed on the piezoelectric substrate and arranged to detect a specific detection object based on a change in output signal; wherein
at least a portion of the comb shaped electrode is electrically conductive and is made of a sensitive material which responds to the specific detection object.

2. The surface acoustic wave sensor according to claim 1, further comprising a reflector disposed on the piezoelectric substrate.

3. A surface acoustic wave sensor comprising:
a piezoelectric substrate;
a comb shaped electrode disposed on the piezoelectric substrate; and
a reflector disposed on the piezoelectric substrate; wherein
the comb shaped electrode and the reflector are arranged on the piezoelectric substrate to detect a specific detection object based on a change in output signal; and
at least a portion of the reflector is made of a sensitive material which responds to the specific detection object.

4. The surface acoustic wave sensor according to claim 3, wherein the sensitive material is electrically conductive.

5. The surface acoustic wave sensor according to claim 1, wherein the comb shaped electrode or the reflector is in contact with the piezoelectric substrate.

6. The surface acoustic wave sensor according to claim 1, wherein all of at least one of the comb shaped electrode and the reflector is made of the sensitive material.

7. The surface acoustic wave sensor according to claim 6, wherein all of the comb shaped electrode and all of the reflector are made of the sensitive material.

8. The surface acoustic wave sensor according to claim 3, wherein all of the reflector is made of the sensitive material.

9. The surface acoustic wave sensor according to claim 1, wherein the comb shaped electrode and the reflector include portions made of mutually different types of the sensitive materials.

10. The surface acoustic wave sensor according to claim 1, further comprising a plurality of the comb shaped electrodes including a plurality of types of comb shaped electrodes made of mutually different types of the sensitive materials.

11. The surface acoustic wave sensor according to claim 1, further comprising a plurality of the reflectors, wherein the plurality of reflectors include a plurality of types of reflectors made of mutually different types of the sensitive materials.

12. The surface acoustic wave sensor according to claim 9, wherein the mutually different types of sensitive materials respond to detection objects different from each other.

13. The surface acoustic wave sensor according to claim 1, wherein the detection object is hydrogen.

14. The surface acoustic wave sensor according to claim 13, wherein the sensitive material is a hydrogen absorbing metal or a hydrogen absorbing alloy.
